(19) United States
(12) Patent Application Publication
(10) Pub. No.: US 2015/0079780 A1
(43) Pub. Date: Mar. 19, 2015

(54) METHOD OF FORMING SEMICONDUCTOR STRUCTURE

(71) Applicant: United Microelectronics Corp., Hsinchu (TW)

(72) Inventors: Yl-Liang Liu, Tainan City (TW); Wu-Sian Sie, Tainan City (TW); Po-Cheng Huang, Kaohsiung City (TW); Chih-Hsien Chen, Miaoli County (TW); I-Lun Hung, Kaohsiung City (TW); Yen-Ming Chen, New Taipei City (TW); Yu-Ting Li, Chiayi City (TW); Chang-Hung Kung, Kaohsiung City (TW); Chun-Hsiung Wang, Kaohsiung City (TW); Chia-Lin Hsu, Tainan City (TW)

(73) Assignee: United Microelectronics Corp., Hsinchu (TW)

(21) Appl. No.: 14/026,634

(22) Filed: Sep. 13, 2013

(51) Int. Cl. H01L 29/66

(52) U.S. Cl. CPC H01L 29/66545; H01L 29/6656
USPC 438/595

(57) ABSTRACT

A method of forming a semiconductor device is disclosed. A gate structure is formed on a substrate. The gate structure includes a dummy gate and a spacer at a sidewall of the dummy gate. A dielectric layer is formed on the substrate outside of the gate structure. A metal hard mask layer is formed to cover tops of the dielectric layer and the spacer and to expose a surface of the gate structure. The dummy gate is removed to form a gate trench. A low-resistivity metal layer is formed on the metal hard mask layer filling in the gate trench. The low-resistivity metal layer outside of the gate trench is removed. The metal hard mask layer is removed.

### BACKGROUND OF THE INVENTION

2. Field of Invention

The present invention relates to a method of forming a semiconductor structure, and more generally to a method of forming a semiconductor device having a metal gate.

2. Description of Related Art

MOS is a basic structure widely applied to various semiconductor devices, such as memory devices, image sensors and display devices. An electric device is required to be made lighter, thinner and smaller. As the CMOS is continuously minimized, a logic CMOS technology is developed towards a technology having a high dielectric constant (high-k) dielectric layer and a metal gate.

The metal gate is usually formed by the following steps. First, a dummy gate is formed on a substrate, and then a dielectric layer is formed on the substrate outside of the dummy gate. Thereafter, the dummy gate is removed to form a gate trench, and then a metal gate is formed in the gate trench. However, during the step of removing the dummy gate, a dishing is usually formed in the top of a spacer at the sidewall of the dummy gate. In such case, metal residues remain in the dishing and the performance of the device is therefore decreased.

### SUMMARY OF THE INVENTION

Accordingly, the present invention provides a method of forming a semiconductor structure, by which the conventional metal residues are not observed so that the performance of the device can be effectively improved.

The present invention provides a method of forming a semiconductor device. A gate structure is formed on a substrate. The gate structure includes a dummy gate and a spacer on a sidewall of the dummy gate. A dielectric layer is formed on the substrate outside of the gate structure. A metal hard mask layer is formed to cover tops of the dielectric layer and the spacer and to expose a surface of the gate structure. The dummy gate is removed to form a gate trench. A low-resistivity metal layer is formed on the metal hard mask layer filling in the gate trench. The low-resistivity metal layer outside of the gate trench is removed. The metal hard mask layer is removed.

According to an embodiment of the present invention, a method of forming the metal hard mask layer comprises: forming a recess in the dielectric layer and in the spacer; and filling the metal hard mask layer in the recess.

According to an embodiment of the present invention, a method of forming the recess comprises performing a chemical mechanical polishing process to remove surface portions of the dielectric layer and the spacer by using the gate structure as a polishing stop layer.

According to an embodiment of the present invention, a method of filling the metal hard mask layer comprises: forming a metal hard mask material layer on the gate structure filling the recess; and performing a chemical mechanical polishing process to remove metal hard mask material layer outside of the recess.

According to an embodiment of the present invention, the step of removing the low-resistivity metal layer outside of the gate trench and the step of removing the metal hard mask layer are performed by a chemical mechanical polishing process.

According to an embodiment of the present invention, a material of the metal hard mask layer is different form a material of the dummy gate.

According to an embodiment of the present invention, a material of the metal hard mask layer is the same as a material of the low-resistivity metal layer.

According to an embodiment of the present invention, a material of the metal hard mask layer comprises W, Al, Cu, or an alloy thereof, or a combination thereof.

According to an embodiment of the present invention, the method of forming a semiconductor device further comprises forming a contact etch stop layer before forming the dielectric layer, and the metal hard mask layer covers the contact etch stop layer.

According to an embodiment of the present invention, the method of forming a semiconductor device further comprises forming a gate dielectric layer, a bottom barrier layer, an etch stop metal layer, a work function metal layer and a top barrier layer in the gate trench.

According to an embodiment of the present invention, the gate dielectric layer is formed before the step of forming the dielectric layer.

According to an embodiment of the present invention, the gate dielectric layer is formed after the step of forming the gate trench.

In view of the above, the present invention provides a method of forming a semiconductor structure, by which a metal hard mask layer is formed on tops of the spacer and the dielectric layer to effectively avoid formation of dishing and thereby the conventional issue of metal residues in the dishing can be settled. Besides, it is easy and simple to integrate the method of the invention into the existing CMOS process, thereby achieving competitive advantages over competitors.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H are schematic cross-sectional views illustrating a method of forming a semiconductor structure according to a first embodiment of the present invention.

FIG. 2A to FIG. 2H are schematic cross-sectional views illustrating a method of forming a semiconductor structure according to a second embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

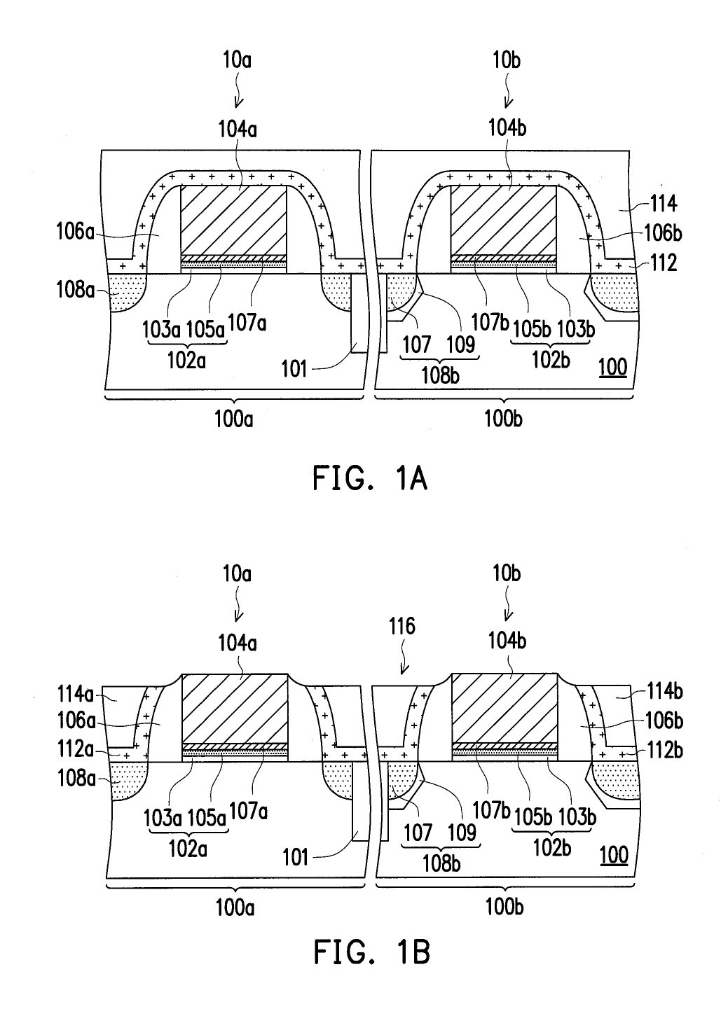

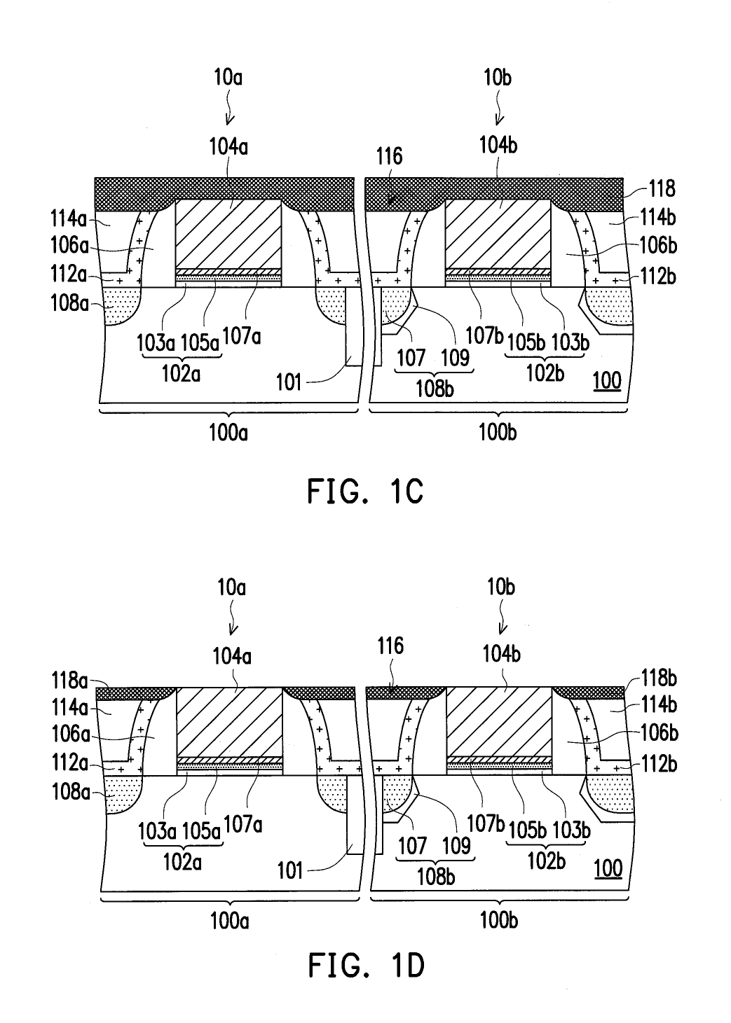

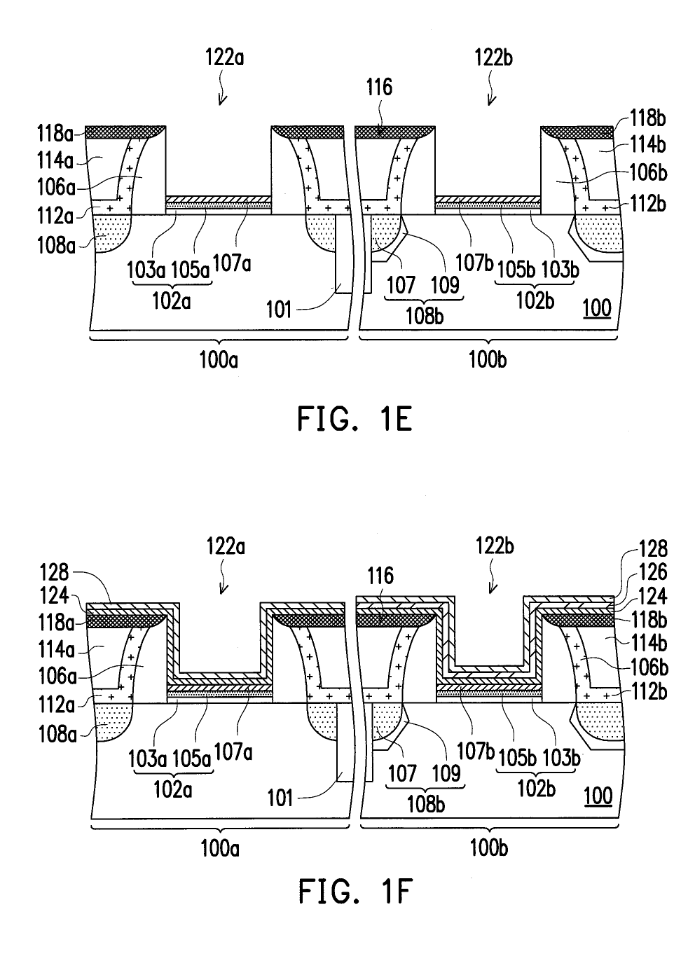

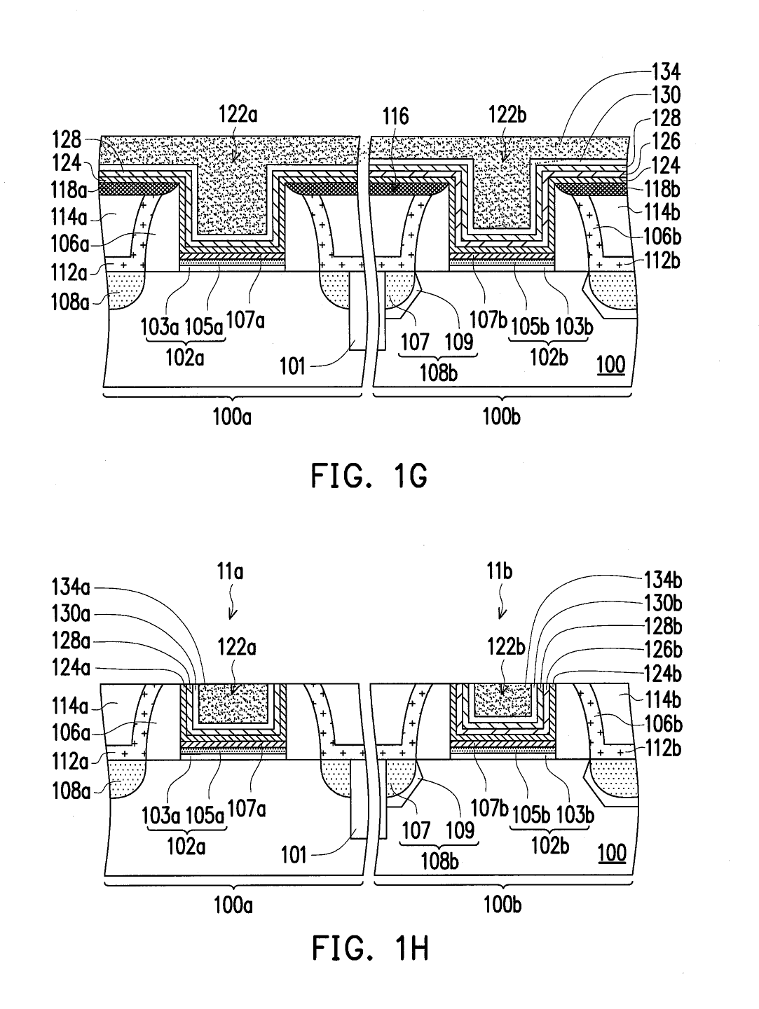

FIG. 1A to FIG. 1H are schematic cross-sectional views illustrating a method of forming a semiconductor structure according to a first embodiment of the present invention. In this embodiment, the method of the invention is integrated with the “high-k first” process for illustration.

Referring to FIG. 1A, at least one gate structure is formed on a substrate 100. The substrate 100 can be a semiconductor substrate, such as a silicon substrate. In this embodiment, the substrate 100 has a first area 100a and a second area 100b, and gate structures 10a and 10b are respectively formed in the first and second areas 100a and 100b, but the present invention is not limited thereto. At least one shallow trench isolation (STI) structure 101 is formed in the substrate 100 between the gate structures 10a and 10b for providing electrical isolation. The first and second areas 100a and 100b are for forming semiconductor devices with different conductivity types. In an embodiment, the first area 100a is for forming an N-type device, and the second area 100b is for forming a P-type device.

The gate structure 10a includes a gate dielectric layer 102a and a dummy gate 104a sequentially formed on the substrate 100. Similarly, the gate structure 10b includes a gate dielectric layer 102b and a dummy gate 104b sequentially formed on the substrate 100. The gate dielectric layer 102a can be a composite layer containing an insulating layer 103a and a high-k layer 105a. Similarly, the gate dielectric layer 102b can be a composite layer containing an insulating layer 103b and a high-k layer 105b. Each of the insulating layers 103a and 103b includes silicon oxide or silicon oxynitride. Each of the high-k layers 105a and 105b includes a high-k material (i.e. a dielectric material with a dielectric constant greater than 4). The high-k material can be metal oxide, such as rare earth metal oxide. The high-k material can be selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), and barium strontium titanate (BaₓSr₁₋ₓTiO₃, BST), wherein x is between 0 and 1. Each of the dummy gates 104a and 104b includes amorphous silicon, crystalline silicon or a combination thereof. The dummy gates 104a and 104b can be doped or undoped.

In addition, a bottom barrier layer 107a is further formed between the high-k layer 105a and the dummy gate 104a. Similarly, a bottom barrier layer 107b is further formed between the high-k layer 105b and the dummy gate 104b. Each of the bottom barrier layers 107a and 107b includes TiN. The bottom barrier layers 107a and 107b have a thickness of 20 angstroms, for example.

The method of forming the gate dielectric layers 102a/102b, the bottom barrier layers 107a-107b and the dummy gates 104a/104b includes stacking required material layers and then patterning the said material layers. The said material layers can be stacked by a furnace process or/and a deposition process such as a physical vapor deposition (PVD) process, chemical vapor deposition (CVD) process or an atomic layer deposition (ALD) process.

Continue referring to FIG. 1A, the gate structure 10a further includes a spacer 106a formed at the sidewall of the dummy gate 104a. Similarly, the gate structure 10b further includes a spacer 106b formed at the sidewall of the dummy gate 104b. Each of the spacers 106a and 106b includes silicon oxide, silicon nitride, silicon oxynitride or a combination thereof. The method of forming the spacers 106a/106b includes depositing a spacer material layer on the substrate 100, and then performing an anisotropic etching process to the spacer material layer.

The gate structure 10a further includes two source/drain regions 108a formed in the substrate 100 beside the dummy gate 104a. Similarly, the gate structure 10b further includes two source/drain regions 108b formed in the substrate 100 beside the dummy gate 104b. In this embodiment, the source/drain regions 108a in the first area 100a can be N-type doped regions, and the source/drain regions 108b in the second area 100b can be combination of P-type doped regions 107 and SiGe layers 109, but the present invention is not limited thereto. In another embodiment, the source/drain regions 108a in the first area 100a can be combination of N-type doped regions and SiC or SiP layers, and the source/drain regions 108b in the second area 100b can be P-type doped regions. In an embodiment, the method of forming the source/drain regions 108a/108b includes the following steps. N-type doped regions are formed in the first area 100a through an ion implantation process. Thereafter, a mask layer (not shown) is formed to cover the first area 100a. Afterwards, recesses (not shown) are formed in the second area 100b beside the dummy gate 104b. SiGe layers 109 are formed in the recesses and P-type doped regions 107 are then formed in the SiGe layers 109 through an ion implantation process.

Referring to FIG. 1A, a contact etch stop layer (CESL) 112 and a dielectric layer 114 are formed on the substrate 100 covering the gate structures 10a and 10b. The CESL 112 includes silicon nitride or a suitable insulating material and the dielectric layer 114 includes silicon oxide, a low-k material, a suitable insulating material or a combination thereof. The CESL 112 and the dielectric layer 114 may be formed by at least one deposition process such as CVD or ALD.

Referring to FIG. 1B, thereafter, portions of the CESL 112 and the dielectric layer 114 are removed so that the top surfaces of the gate structures 10a and 10b are exposed, and the CESLs 112a/112b and the dielectric layers 114a/114b remain between the gate structures 10a and 10b and at outer sides of the gate structures 10a and 10b. The CESLs 112a/112b, the dielectric layers 114a/114b and the spacers 106a/106b have recesses 116 formed in surface portions thereof. The removing step includes performing a chemical mechanical polishing (CMP) process by using the gate structures 10a and 10b as a polishing stop layer.

Referring to FIG. 1C, a metal hard mask material layer 118 is formed over the substrate 100 covering the gate structures 10a and 10b and filling the recesses 116. The material of the metal hard mask material layer 118 is different from the material of the dummy gate 104a and 104b. In an embodiment, the material of the metal hard mask material layer 118 may be the same as the material of a low-resistivity metal material layer 134 (as shown in FIG. 1G) to be filled in gate trenches 122a and 122b (as shown in FIG. 1E). The metal hard mask material layer 118 includes W, Al, Cu or an alloy thereof, or a combination thereof, and the forming method thereof includes performing a deposition process such as PVD or CVD.

Referring to FIG. 1D, the metal hard mask material layer 118 outside of the gate recesses 116 is removed, so as to expose the top surfaces of the gate structures 10a and 10b and therefore form metal hard mask layers 118a and 118b in the recesses 116 respectively in the first and second areas 100a and 100b. The metal hard mask layers 118a/118b cover the spacers 106a/106b and the CESLs 112a/112b and the dielectric layers 114a/114b. The removing step includes performing a CMP process by using the gate structures 10a and 10b as a polishing stop layer.

Referring to FIG. 1E, thereafter, the dummy gates 104a and 104b of the gate structures 10a and 10b are removed to form gate trenches 122a and 122b in the dielectric layer 114. The removing step can be a dry etching step, a wet etching step or a combination thereof. During the removing step, the spacers 106a/106b and the CESLs 112a/112b and the dielectric layers 114a/114b are protected by the metal hard mask layers 118 a/118b.

Referring to FIG. 1F, an etch stop metal layer 124 is formed on the substrate 100 filling in the gate trenches 122a and 122b. The etch stop metal layer 124 includes TaN and the forming method thereof includes performing a deposition process such as PVD, CVD or ALD. Thereafter, a first work function metal layer 126 is formed in the gate trench 122b in the second area 100b. In the present embodiment in which a P-type device is formed in the second area 100b, the first work function metal layer 126 includes titanium nitride (TiN), titanium carbide (TiC), tantalum nitride (TaN), tantalum carbide (TaC), tungsten carbide (WC) or aluminum titanium nitride (TiAlN). The method of forming the first work function metal layer 126 includes the following steps. A first work function metal material layer (not shown) is formed on the etch stop metal layer 124 by a radio frequency PVD (RFPVD) process. The first work function metal material layer has a thickness of about 100 angstroms, for example. Thereafter, a mask layer (not shown) is formed to cover the second area 100b. Afterwards, the first work function metal material layer in the first area 100a is removed. The mask layer (not shown) is removed.

Thereafter, a second work function metal layer 128 is formed on the substrate 100 filling in the gate trenches 122a and 122b. In the present embodiment in which an N-type device is formed in the first area 100a, the second work function metal layer 128 includes titanium aluminide (TiAl), zirconium aluminide (ZrAl), tungsten aluminide (WAl), tantalum aluminide (TaAl) or hafnium aluminide (HfAl). The method of forming the second work function metal layer 128 includes performing a radio frequency PVD (RFPVD) process. The second work function metal layer 128 has a thickness of about 100 angstroms, for example.

Referring to FIG. 1G, a top barrier layer 130 is formed on the second work function metal layer 128. In an embodiment, the top barrier layer 130 includes a TiN layer. The method of forming the top barrier layer 130 includes performing at least one deposition process (e.g. PVD, CVD or ALD). The top barrier layer 130 has a thickness of about 40 angstroms, for example.

Thereafter, a low-resistivity metal material layer 134 is formed on the substrate 100 filling up the gate trenches 122a and 122b. The low-resistivity metal material layer 134 includes W, Al, Cu or an alloy thereof, or a combination thereof, and the forming method thereof includes performing a deposition process such as PVD or CVD.

Referring to FIG. 1H, the metal hard mask layers 118a/118b and the unnecessary layers including the low-resistivity metal material layer 134, the top barrier layer 130, the second work function metal layer 128, the first work function metal layer 126 and the etch stop metal layer 124 outside of the gate trenches 122a and 122b are removed through the same removing step, so as to form a low-resistivity metal material layer 134a, a top barrier layer 130a, a second work function metal layer 128a, and an etch stop metal layer 124a in the gate trench 122a, and simultaneously form a low-resistivity metal material layer 134b, a top barrier layer 130b, a second work function metal layer 128b, a first work function metal layer 126b, and an etch stop metal layer 124b in the gate trenches 122b. The said removing step includes performing a CMP process. As a result, an N-MOS device 11a is formed in the first area 100a and a P-type device 11b is formed in the second area 100b.

The said embodiment of the “high-k first” process is provided for illustration purposes, and is not construed as limiting the present invention. Another embodiment can be integrated with the “high-k last” process.

### Second Embodiment

The second embodiment is similar to the first embodiment. The difference between first and second embodiments is described in the following, and the similarities are not iterated herein.

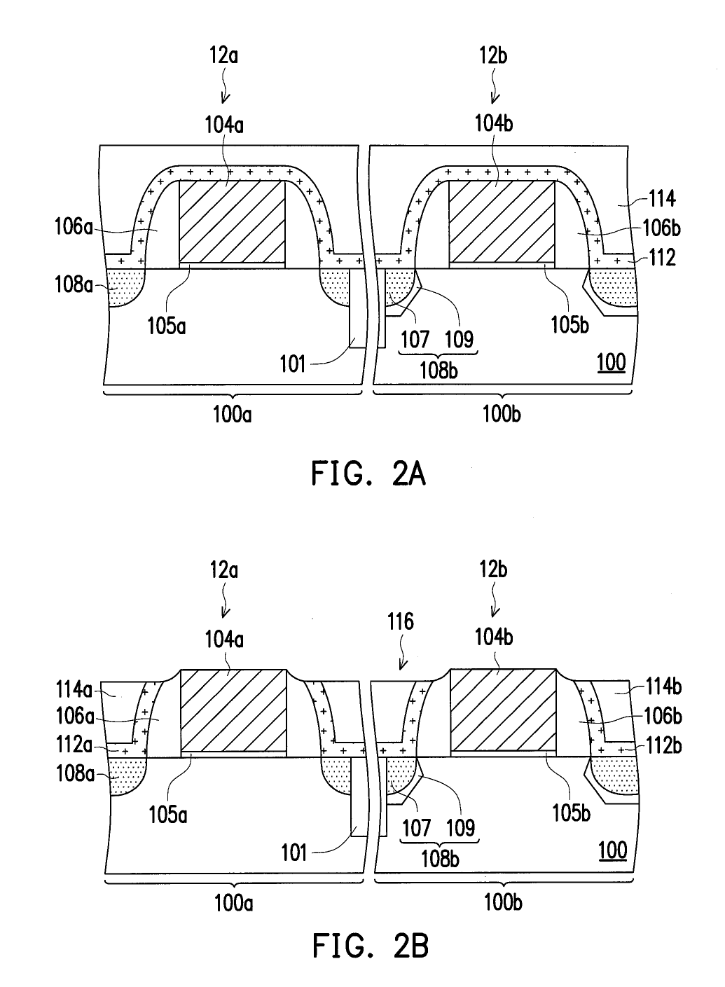

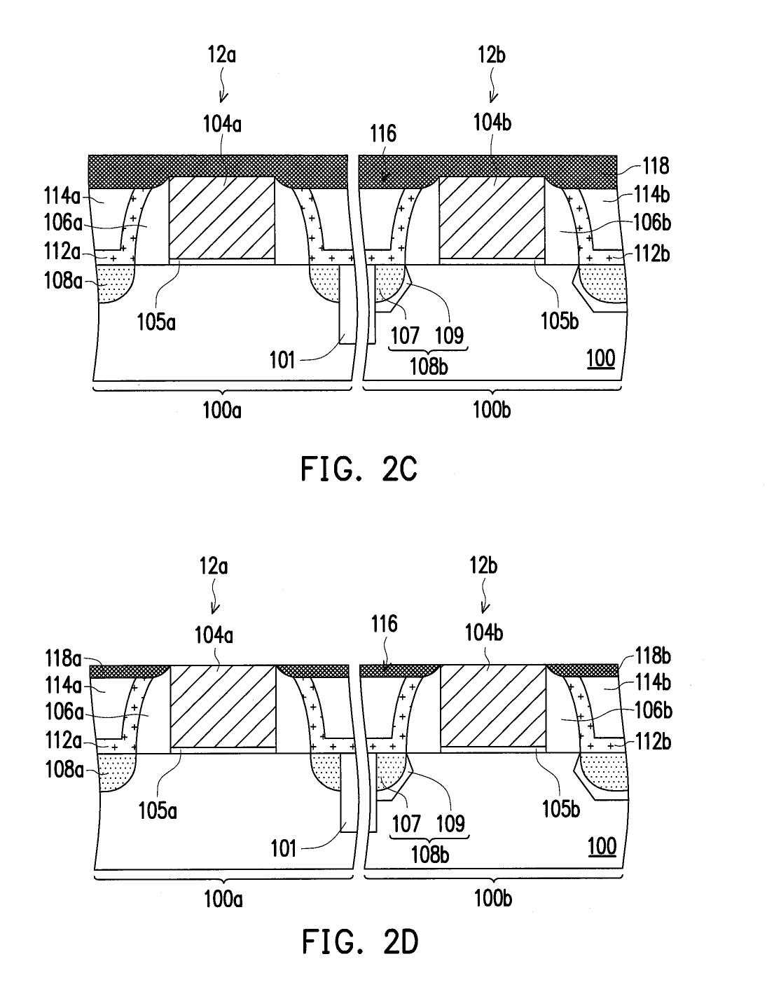

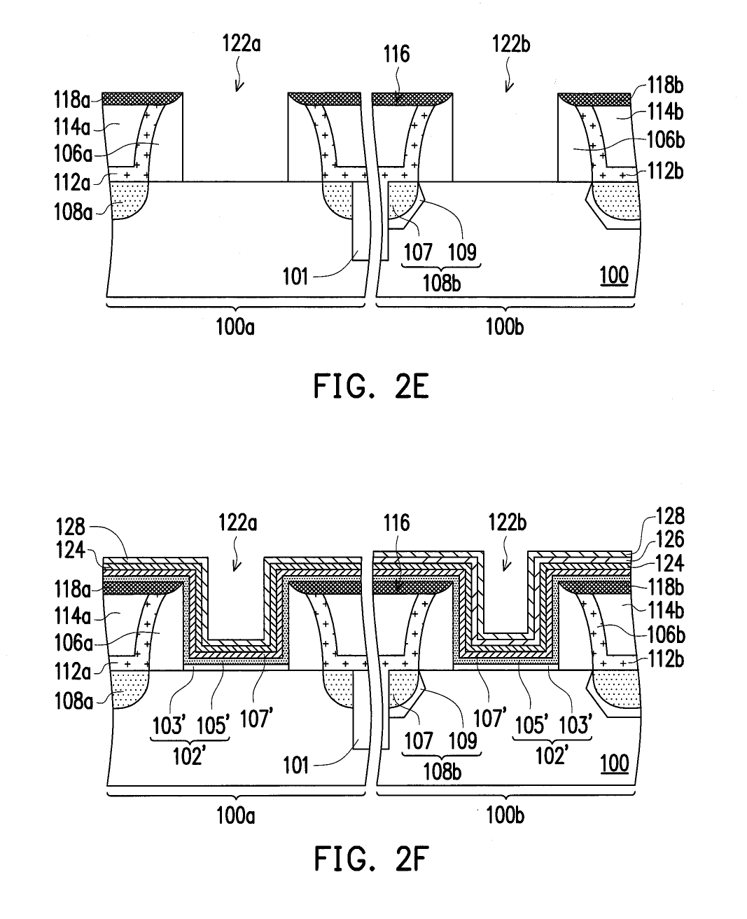

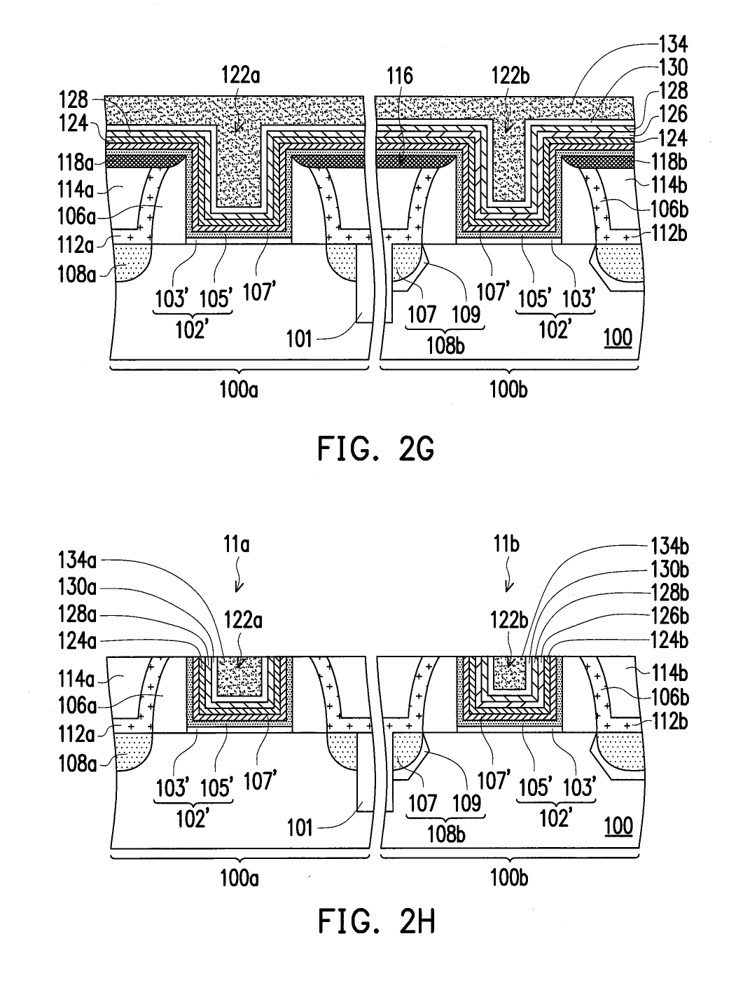

FIG. 2A to FIG. 2G are schematic cross-sectional views illustrating a method of forming a semiconductor structure according to a second embodiment of the present invention.

Referring to FIG. 2A, at least one gate structure is formed on a substrate 100. The substrate 100 has a first area 100a and a second area 100b, and gate structures 12a and 12b are respectively formed in the first and second areas 100a and 100b. At least one STI structure 101 is formed in the substrate 100 between the gate structures 10a and 10b for providing electrical isolation. The first and second areas 100a and 100b are for forming semiconductor devices with different conductivity types. In an embodiment, the first area 100a is for forming an N-type device, and the second area 100b is for forming a P-type device.

The gate structure 12a includes an interfacial layer 150a and a dummy gate 104a sequentially formed on the substrate 100. Similarly, the gate structure 12b includes an interfacial layer 150b and a dummy gate 104b sequentially formed on the substrate 100. Each of the interfacial layers 150a and 150b includes silicon oxide, and the forming method thereof includes performing a furnace process (e.g. thermal oxidation). Each of the dummy gates 104a and 104b includes amorphous silicon, crystalline silicon or a combination thereof, and the forming method thereof includes performing a deposition process (e.g. ALD or CVD).

Continue referring to FIG. 2A, the gate structure 12a further includes a spacer 106a formed at the sidewall of the dummy gate 104a. Similarly, the gate structure 12b further includes a spacer 106b formed at the sidewall of the dummy gate 104b. Besides, the gate structure 12a further includes two source/drain regions 108a formed in the substrate 100 beside the dummy gate 104a. Similarly, the gate structure 12b further includes two source/drain regions 108b formed in the substrate 100 beside the dummy gate 104b. In this embodiment, the source/drain regions 108a in the first area 100a can be N-type doped regions, and the source/drain regions 108b in the second area 100b can be combination of P-type doped regions 107 and SiGe layers 109, but the present invention is not limited thereto. A contact etch stop layer (CESL) 112 and a dielectric layer 114 are formed on the substrate 100.

Referring to FIG. 2B, thereafter, portions of the CESL 112 and the dielectric layer 114 are removed so that recesses 116 are formed in surface portions of the CESLs 112a/112b, the dielectric layers 114a/114b and the spacers 106a/106b.

Referring to FIG. 2C, a metal hard mask material layer 118 is formed over the substrate 100 covering the gate structures 10a and 10b and filling the recesses 116.

Referring to FIG. 2D, the metal hard mask material layer 118 outside of the gate recesses 116 is removed, so as to form metal hard mask layers 118a and 118b in the recesses 116.

Referring to FIG. 2E, thereafter, the dummy gates 104a and 104b and the interfacial layers 150a and 150b of the gate structures 12a and 12b are removed to form gate trenches 122a and 122b in the dielectric layer 114. During the removing step, the spacers 106a/106b and the CESLs 112a/112b and the dielectric layers 114a/114b may be protected by the metal hard mask layers 118a/118b.

Referring to FIG. 2F, a gate dielectric layer 102′ is formed on the surfaces of the gate trenches 122a and 122b. The gate dielectric layer 102′ can be a composite layer containing an insulating layer 103′ and a high-k layer 105′. The insulating layer 103′ includes silicon oxide and the forming method thereof includes performing a furnace process (e.g. thermal oxidation). The high-k layer 105′ includes a high-k material and the forming method the forming method thereof includes performing a deposition process (e.g. ALD or CVD). In this embodiment, the high-k layer 105′ of the gate dielectric layer 102′ can be formed on the bottoms and sidewalls of the gate trenches 122a and 122b. Thereafter, a bottom barrier layer 107′ is formed on the gate dielectric layer 102′.

In view of the above, the substrate 100 has the dielectric layer 114a formed thereon. The dielectric layer 114a has the gate trenches 122a and 122b formed therein. The gate dielectric layer 102′ is formed at least on the bottoms of the gate trenches 122a and 122b. Besides, the gate dielectric layer 102′ (see FIG. 2F) is formed after the step of forming the gate trenches 122a and 122b (see FIG. 2E).

Continue referring to FIGS. 2F, an etch stop metal layer 124 is formed on the substrate 100 filling in the gate trenches 122a and 122b. Thereafter, a first work function metal layer 126 is formed in the gate trench 122b in the second area 100b. Afterwards, a second work function metal layer 128 is formed on the substrate 100 filling in the gate trenches 122a and 122b.

Referring to FIG. 2G, a top barrier layer 130 is formed on the second work function metal layer 128. Thereafter, a low-resistivity metal material layer 134 is formed on the substrate 100 filling up the gate trenches 122a and 122b.

Referring to FIG. 2H, the metal hard mask layers 118a/118b and the unnecessary layers including the low-resistivity metal material layer 134, the top barrier layer 130, the second work function metal layer 128, the first work function metal layer 126, the etch stop metal layer 124 outside of the gate trenches 122a and 122b are removed, so as to form a low-resistivity metal material layer 134a, a top barrier layer 130a, a second work function metal layer 128a, and an etch stop metal layer 124a in the gate trench 122a, and simultaneously form a low-resistivity metal material layer 134b, a top barrier layer 130b, a second work function metal layer 128b, a first work function metal layer 126b, and an etch stop metal layer 124b in the gate trench 122b. As a result, an N-MOS device 11a is formed in the first area 100a and a P-type device 11b is formed in the second area 100b.

In summary, in the present invention, the metal hard mask layers are formed in the recesses on the top surfaces of the spacers, the contact etch stop layers and the dielectric layers between the gate structures and at outer sides of the gate structures. During the removing step of the dummy gates, the spacers, the contact etch stop layers and the dielectric layers may be protected by the metal hard mask layers to avoid formation of dishing. Therefore, the conventional issue of metal residues in the dishing can be settled. In addition, since the material of the metal hard mask layers may be the same as that of the low-resistivity metal material layer, the metal hard mask layers can be simultaneously removed during the step of removing the unnecessary layers outside of the gate trenches. Therefore, it is easy and simple to integrate the method of the invention into the existing CMOS process, thereby achieving competitive advantages over competitors.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

1. A method of forming a semiconductor device, comprising:
forming a gate structure on a substrate, the gate structure comprising a dummy gate and a spacer at a sidewall of the dummy gate;
forming a dielectric layer on the substrate outside of the gate structure;
forming a metal hard mask layer to cover tops of the dielectric layer and the spacer and to expose a surface of the gate structure;
removing the dummy gate to form a gate trench after the step of forming the metal hard mask layer;
forming a low-resistivity metal layer on the metal hard mask layer filling in the gate trench;
removing the low-resistivity metal layer outside of the gate trench; and
removing the metal hard mask layer.

2. The method of claim 1, wherein a method of forming the metal hard mask layer comprises:
forming a recess in the dielectric layer and in the spacer; and
filling the metal hard mask layer in the recess.

3. The method of claim 2, wherein a method of forming the recess comprises performing a chemical mechanical polishing process to remove surface portions of the dielectric layer and the spacer by using the gate structure as a polishing stop layer.

4. The method of claim 2, wherein a method of filling the metal hard mask layer comprises:
forming a metal hard mask material layer on the gate structure filling the recess; and
performing a chemical mechanical polishing process to remove metal hard mask material layer outside of the recess.

5. The method of claim 1, wherein the step of removing the low-resistivity metal layer outside of the gate trench and the step of removing the metal hard mask layer are performed by a chemical mechanical polishing process.

6. The method of claim 1, wherein a material of the metal hard mask layer is different form a material of the dummy gate.

7. The method of claim 1, wherein a material of the metal hard mask layer is the same as a material of the low-resistivity metal layer.

8. The method of claim 1, wherein a material of the metal hard mask layer comprises W, Al, Cu, or an alloy thereof, or a combination thereof.

9. The method of claim 1, further comprising forming a contact etch stop layer before forming the dielectric layer, wherein the metal hard mask layer covers the contact etch stop layer.

10. The method of claim 1, further comprising forming a gate dielectric layer, a bottom barrier layer, an etch stop metal layer, a work function metal layer and a top barrier layer in the gate trench.

11. The method of claim 10, wherein the gate dielectric layer is formed before the step of forming the dielectric layer.

12. The method of claim 10, wherein the gate dielectric layer is formed after the step of forming the gate trench.
